(19) United States
(12) Patent Application Publication
(10) Pub. No.: US 2008/0003755 A1
(43) Pub. Date: Jan. 3, 2008

(54) Sacrificial oxide layer which enables spacer over-etch in tri-gate architectures

(76) Inventors: Uday Shah, Portland, OR (US); Willy Rachmady, Beaverton, OR (US); Jack T. Kavalieros, Portland, OR (US); Brian S. Doyle, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/479,713

(22) Filed: Jun. 30, 2006

(51) Int. Cl. H01L 21/336

(52) U.S. Cl. 438/300; 257/E21.619

(57) ABSTRACT

Embodiments of methods and apparatus for a sacrificial oxide layer which enables spacer over-etch in multi-gate architectures are generally described herein. Other embodiments may be described and claimed.

### FIELD OF THE INVENTION

The field of invention relates generally to the field of semiconductor integrated circuit manufacturing and, more specifically but not exclusively, relates to CMOS (complementary metal oxide semiconductor) devices having a three-dimensional tri-gate fin body lacking spacers or dry etch damage on the side walls of the tri-gate fin body.

### BACKGROUND INFORMATION

In a conventional metal oxide semiconductor field effect transistor (MOSFET), the source, channel, and drain structures are constructed adjacent to each other within the same plane. The gate dielectric is formed on the channel area and the gate electrode is deposited on the gate dielectric. The transistor is controlled by applying a voltage to the gate electrode thereby allowing a current to flow through the channel between source and drain.

An alternative to methods of building planar MOSFETs has been proposed to help alleviate some of the physical barriers to scaling down existing designs. The alternative method involves a construction of three dimensional MOSFETs, in the form of a multi-gate transistor such as a dual-gate field effect transistor (FinFET) or a tri-gate transistor, as a replacement for the conventional planar MOSFET.

Three-dimensional transistor designs such as the dual-gate FinFET and the tri-gate transistor allow tighter packing of the same number of transistors on a semiconductor chip by using vertical or angled surfaces for the gates. A tri-gate device comprises three equal length gates situated on three exposed surfaces of a semiconductor body.

An overall contact resistance of the tri-gate device is a function of a contact resistance contributed by the top gate and a contact resistance contributed by each of the two side gates. The contact resistance at each gate is determined in part by the contact area of the source and drain, materials used at the interface of the source and drain regions, such as a silicide layer, and the manner in which those materials interface. The silicide layer may be formed on the source and drain regions for the top and side gates of a multi-gate device to reduce the contact resistance, thereby increasing the transistor current. The contact resistance can increase when a portion of the silicide material is blocked or is otherwise prevented from contacting a source or drain region.

Thus, there is a general need for maximizing the available contact area for the source drain regions in a multi-gate device. By increasing the area of contact in the source and drain regions and reducing the overall contact resistance, the transistor current for the multi-gate device can be increased.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a flowchart describing an embodiment of a fabrication process used to create a silicide layer on a top surface and a side surface of a tri-gate field effect transistor.

FIG. 2 is an illustration of a cross-sectional view of a tri-gate field effect transistor after forming a dielectric layer for a spacer.

FIG. 3 illustrates the transistor in FIG. 2 after eroding a portion of the dielectric layer to expose a top surface of the semiconductor body.

FIG. 4A illustrates the transistor in FIG. 3 after forming a sacrificial layer on the top surface of the semiconductor body.

FIG. 4B is a cross-sectional view of the transistor of FIG. 4A taken through section line 4B-4B of FIG. 4A. This view illustrates dielectric spacers formed on a front surface and a back surface of the semiconductor body.

FIG. 5A illustrates the transistor of FIG. 4A after eroding a portion of the dielectric layer to expose a side surface of the semiconductor body.

FIG. 5B is a cross-sectional view of the transistor of FIG. 5A taken through section line 5B-5B of FIG. 5A. This view illustrates the erosion of the dielectric spacers from the front surface and the back surface of the semiconductor body.

FIG. 6 illustrates the transistor of FIG. 5A after eroding the sacrificial layer from the top surface of the semiconductor body.

FIG. 7A illustrates the transistor of FIG. 6 after forming an epitaxial layer on a top surface and a side surface of the semiconductor body.

FIG. 7B is a cross-sectional view of the transistor of FIG. 7A taken through section line 7B-7B of FIG. 7A. This view illustrates the formation of the epitaxial layer on a front surface and a back surface of the semiconductor body.

FIG. 7C illustrates the transistor of FIG. 6 after forming an alternate epitaxial layer on a top surface and a side surface of the semiconductor body.

FIG. 7D is a cross-sectional view of the transistor of FIG. 7C taken through section line 7D-7D of FIG. 7C. This view illustrates the formation of an alternate epitaxial layer on a front surface and a back surface of the semiconductor body.

FIG. 8A illustrates the transistor of FIG. 7A after forming a silicide layer on the epitaxial layer on the top surface and the side surface of the semiconductor body.

FIG. 8B is a cross-sectional view of the transistor of FIG. 8A taken through section line 8B-8B of FIG. 8A. This view illustrates the formation of a silicide layer on the epitaxial layer on the front surface and the back surface of the semiconductor body.

FIG. 8C illustrates the transistor of FIG. 7C after forming a silicide layer on an alternate epitaxial layer on the top surface and the side surface of the semiconductor body.

FIG. 8D is a cross-sectional view of the transistor of FIG. 8C taken through section line 8D-8D of FIG. 8C. This view illustrates the formation of a silicide layer on an alternate epitaxial layer on the front surface and the back surface of the semiconductor body.

### DETAILED DESCRIPTION

Embodiments of methods and apparatus for a three-dimensional multi-gate transistor device with a dielectric spacer adjacent to a gate electrode and a silicide layer on a top surface and a side surface of a semiconductor body are described herein. In the following description, numerous specific details are set forth in order to provide a thorough understanding of embodiments of the present invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

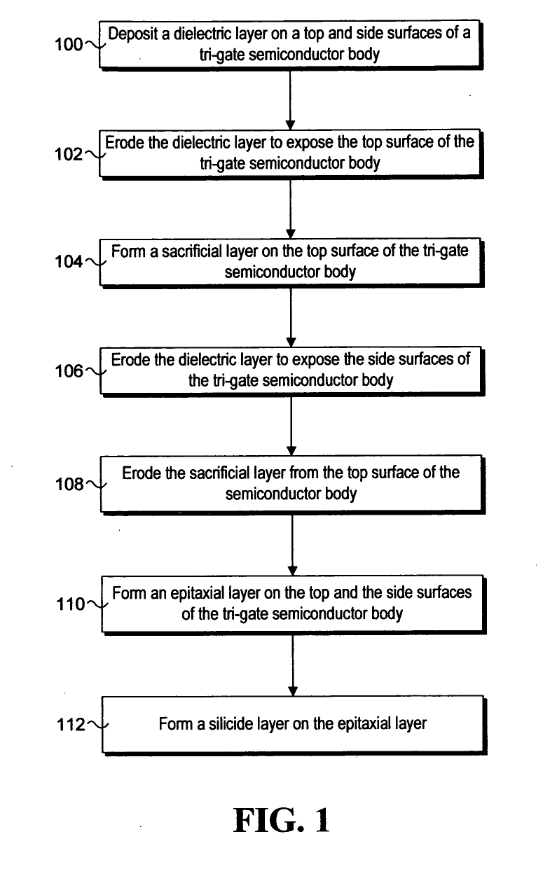

One embodiment for how a three-dimensional multi-gate transistor device with a dielectric spacer adjacent to a gate electrode and a silicide layer on the top and side surfaces of a semiconductor body may be formed is described in FIG. 1. The process may be initiated (element 100) by depositing a dielectric layer on a top surface and at least one side surface of a semiconductor body. The dielectric layer may comprise a nitride layer such as silicon nitride, titanium nitride, or silicon oxynitride, but the embodiment is not so limited. The dielectric layer may be deposited using methods known to persons having ordinary skill in the art, such as plasma enhanced chemical vapor deposition (PECVD), high density chemical vapor deposition (HDCVD), or sputtering, but the embodiment is not so limited. The semiconductor body may be formed, for example, from a monocrystalline substrate or from a silicon-on-insulator (SOI) layer.

The dielectric layer is then eroded (element 102) to expose the top surface of the semiconductor body. In one embodiment, the dielectric layer may be eroded by a dry-etch process using sulfur hexafluoride (SF6) or a fluorinated hydrocarbon (CHxFy) gas in a magnetically enhanced reactive ion etching (MERIE) or an electron cyclotron resonance (ECR) chamber or tool. The dry-etch process may be terminated by using a timing mechanism or by sensing a silicon layer on the top surface of the semiconductor body. However, the dielectric material may also be eroded using a wet-etch process, or an ion milling process. In one embodiment, the wet-etch process may comprise a hydrofluoric acid (HF) or a hot phosphoric acid (H3PO4) solution.

After eroding the dielectric layer, a sacrificial layer (element 104) is formed on the top surface of the semiconductor body. The sacrificial layer, or protective layer, is formed to protect the top surface of the semiconductor body during subsequent processing. In one embodiment, the sacrificial masking layer may be an oxide layer formed using a chemical vapor deposition (CVD) chamber, but the embodiment is not so limited. The dielectric layer is then further eroded (element 106) to expose at least one side surface of the semiconductor body. In one embodiment, the dielectric layer may be eroded by a dry-etch process using sulfur hexafluoride (SF6) or a fluorinated hydrocarbon (CHxFy) gas in a MERIE or an ECR chamber or tool.

The sacrificial layer is eroded (element 108) to expose a top surface of the semiconductor body. The sacrificial layer may be eroded using a wet-etch process or a dry-etch process that selectively etches the sacrificial layer while leaving remaining structures largely intact. In one embodiment, the wet-etch process may comprise an HF or a buffered HF solution. At least one side surface and a top surface of the semiconductor body is exposed and a dielectric spacer remains adjacent to a gate electrode on the semiconductor body following the erosion of the sacrificial layer. The semiconductor body is then thickened by forming an epitaxial layer (element 110) on the top and at least one side surface of the semiconductor body. Typically, the epitaxial layer will form in areas where monocrystalline silicon is exposed.

In one embodiment, a silicide layer may be formed (element 112) on the exposed epitaxial layer using a physical vapor deposition (PVD) or a chemical vapor deposition (CVD) technique and a subsequent high temperature step, although the scope of the invention is not limited in this respect.

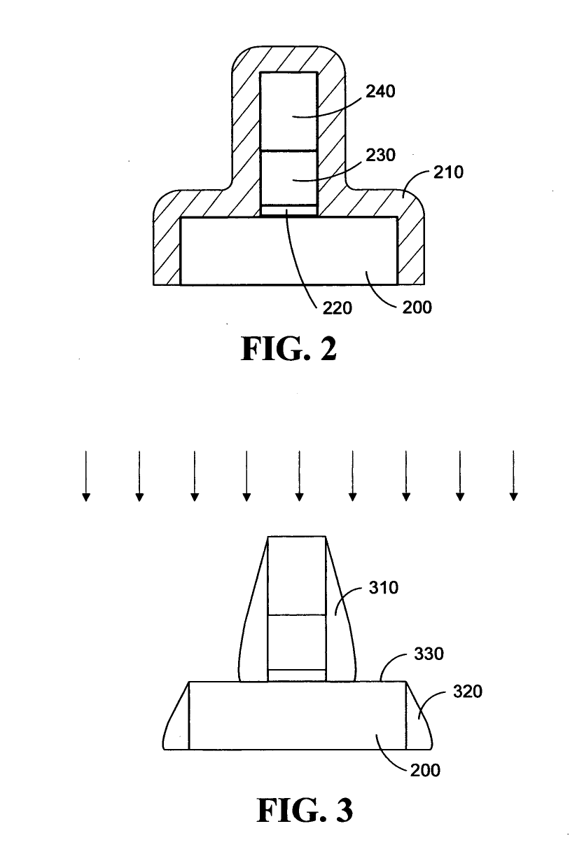

The method for how a three-dimensional multi-gate transistor device with a dielectric spacer adjacent to a gate electrode and a silicide layer on the top and side surfaces of a semiconductor body may be formed is illustrated in FIG. 2 through FIG. 8D. FIG. 2 illustrates a cross-sectional view of a tri-gate field effect transistor comprising a semiconductor body 200 and a gate electrode comprising a thin gate dielectric layer 220, a conductive layer 230, and a hard mask layer 240. The thin gate dielectric layer 220 may comprise a silicon oxide, or alternatively, a high-k dielectric layer such as lanthanum oxide, tantalum oxide, titanium oxide, hafnium oxide, zirconium oxide, lead-zirconate-titanate (PZT), barium-strontium-titanate (BST), or aluminum oxide. In one embodiment, the high-k dielectric layer is between 15 angstroms and 30 angstroms in thickness, although these values for the dielectric layer are not limiting. The conductive layer 230 may comprise doped or un-doped polysilicon, or a metal film such as tungsten, tantalum, titanium and/or nitrides and alloys thereof as the conductive path for the gate electrode. The hard mask layer 240 may comprise a silicon dioxide, silicon nitride, or silicon oxynitride layer, but the embodiment is not limited to these materials. A dielectric layer 210 may be deposited on the tri-gate field effect transistor. The dielectric layer 210 may comprise silicon nitride, silicon oxynitride, or silicon carbide, but the embodiment is not so limited.

FIG. 3 illustrates the transistor in FIG. 2 after eroding a portion of the dielectric layer 210 to form a gate electrode spacer 310 and a semiconductor body spacer 320, and exposing a top surface 330 of the semiconductor body 200. In one embodiment, the dielectric layer 210 may be eroded to form the gate electrode spacer 310 and the semiconductor body spacer 320 using sulfur hexafluoride (SF6), oxygen (O2), carbon monoxide (CO), and argon (Ar), or a fluorinated hydrocarbon (CHxFy) gas in a MERIE or an ECR chamber or tool.

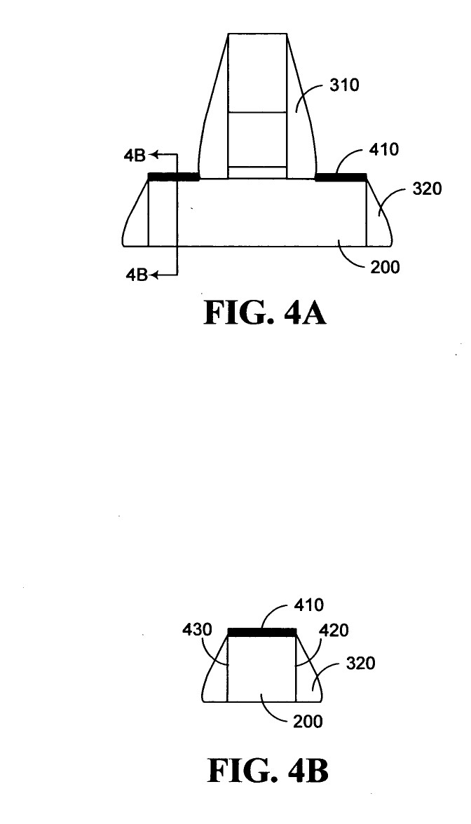

Turning to FIG. 4A, a sacrificial layer 410 is formed on the top surface 330 of the semiconductor body 200. The sacrificial layer 410 is formed to protect the top surface 330 of the semiconductor body 200 during subsequent processing of the gate electrode spacer 310 and the semiconductor body spacer 320. In one embodiment, the sacrificial layer 410 acts as a mask and may be an oxide layer formed using a chemical vapor deposition (CVD) chamber, a wet chemical passivation method, or through native oxide growth by exposure to an ambient environment, but the embodiment is not so limited. The illustration of FIG. 4B, a cross-section through section line 4B-4B of FIG. 4A, shows that a front 420 and a back 430 of the semiconductor body 200 with the sacrificial layer 410 may have an adjacently positioned semiconductor body spacer 320.

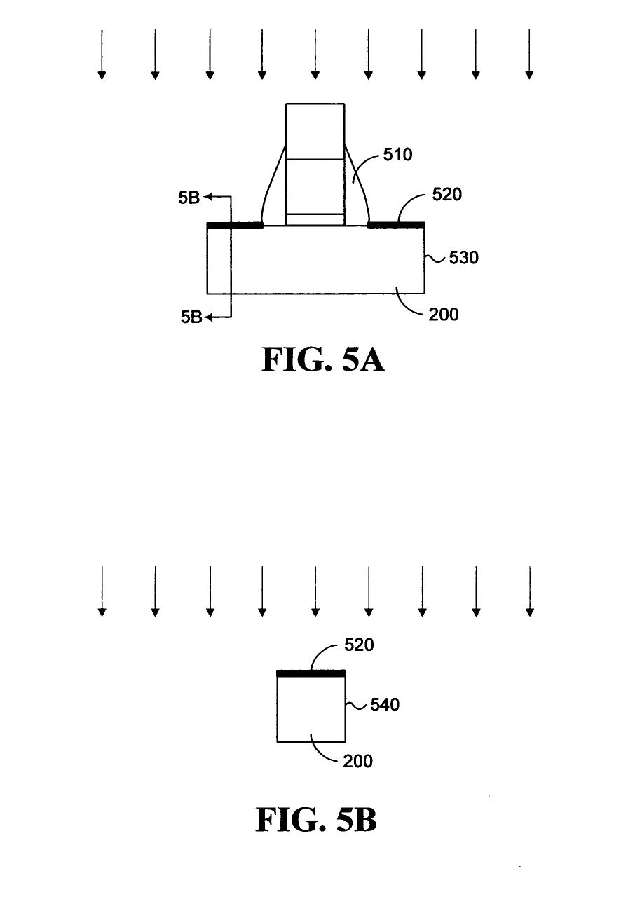

FIG. 5A illustrates the transistor of FIG. 4A after eroding a portion of the dielectric layer to expose a side surface 530 of the semiconductor body 200. A sacrificial layer 520 may be minimally eroded during this process. A gate electrode spacer 510 may also be eroded during this process. In one embodiment, the sacrificial layer 520 and the gate electrode spacer may be eroded using sulfur hexafluoride (SF6) or a fluorocarbon (CxFy) gas in a MERIE or an ECR chamber or tool. The illustration of FIG. 5B, a cross-section through section line 5B-5B of FIG. 5A, shows the semiconductor body 200 and sacrificial layer 520 with an exposed front surface 540.

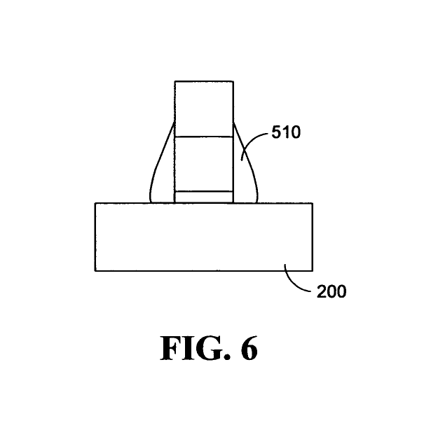

FIG. 6 illustrates the transistor of FIG. 5A with a gate electrode spacer 510 after eroding the sacrificial layer 520 from a top surface of the semiconductor body 200. The sacrificial layer 520 may be eroded using a wet-etch process or a dry-etch process. In one embodiment, the wet-etch process may comprise an HF or a buffered HF solution, although the scope of the invention is not limited in this respect.

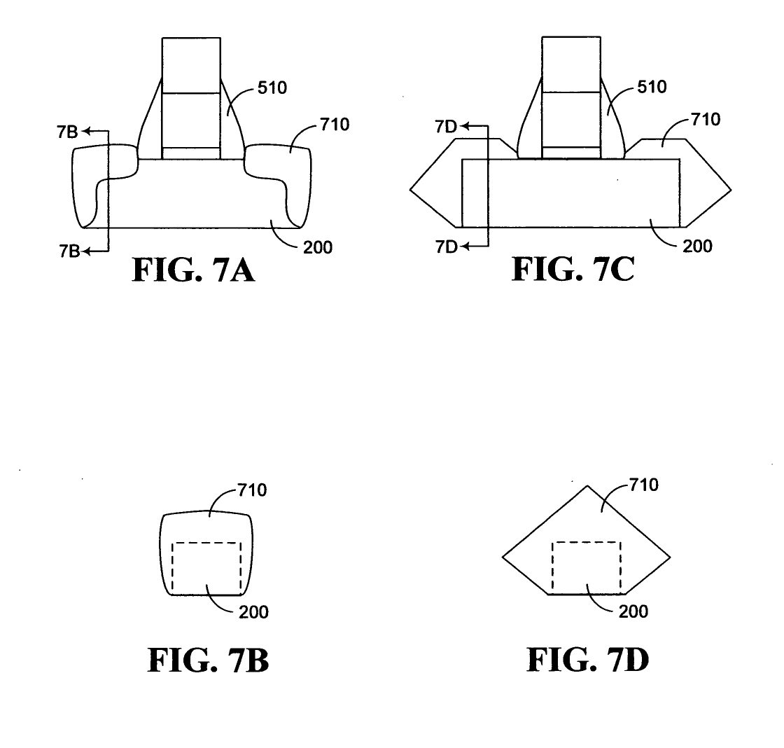

An epitaxial layer 710 is deposited adjacent to a gate electrode spacer 510 on a top surface and a side surface of the semiconductor body 200 after eroding the sacrificial layer 520. FIG. 7A illustrates one embodiment of the transistor of FIG. 6 after forming the epitaxial layer 710. FIG. 7C illustrates another embodiment of the transistor of FIG. 6 after forming an alternate epitaxial layer 710. The illustration of FIG. 7B, a cross-section through section line 7B-7B of FIG. 7A, shows an embodiment with an epitaxial layer 710 formed on a front and a back as well as the top of the semiconductor body 200. FIG. 7D illustrates the structure of FIG. 7B with an alternate epitaxial layer 710. The epitaxial layer 710 may be formed using a CVD chamber using a source gas such as silane, or by molecular beam epitaxy (MBE), though the invention is not limited in this respect.

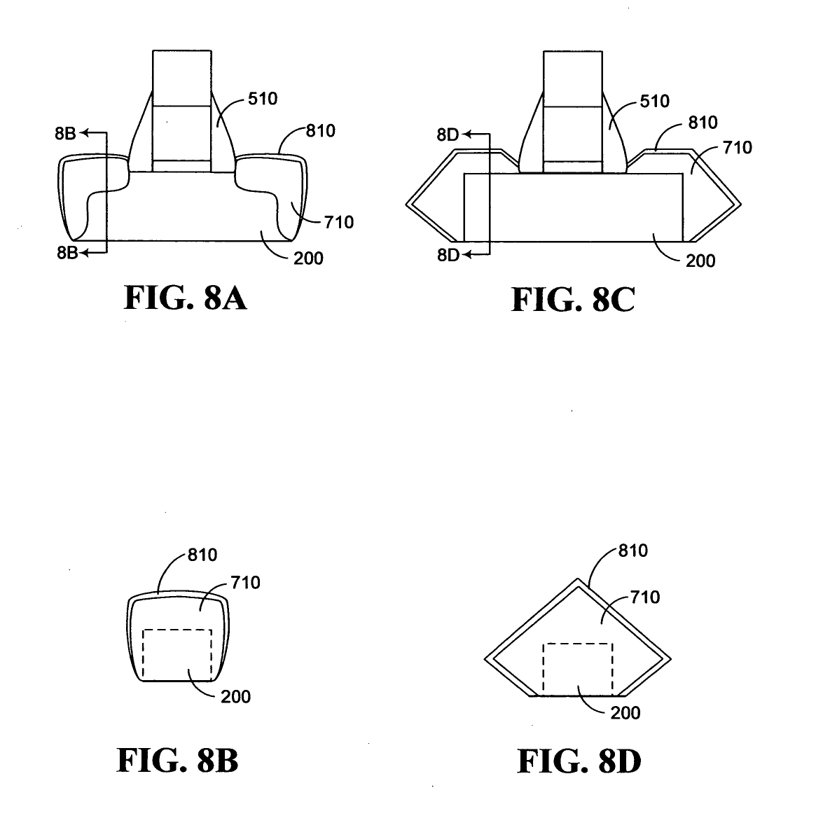

A silicide layer 810 is deposited adjacent to a gate electrode spacer 510 on a top surface and a side surface of the semiconductor body 200 and the epitaxial layer 710. FIG. 8A illustrates one embodiment of the transistor of FIG. 7A after forming the silicide layer 810. FIG. 8C illustrates another embodiment of the transistor of FIG. 7C after forming the silicide layer 810. FIG. 8B is a cross-sectional illustration of section line 8B-8B of FIG. 7B, which shows one embodiment with a silicide layer 810 formed on a front and a back as well as the top of the semiconductor body 200 and the epitaxial layer 710. FIG. 8D illustrates the structure of FIG. 8B with an alternate epitaxial layer 710. The silicide layer 810 may be formed on the exposed epitaxial layer 710 by depositing a metal such as titanium (Ti), cobalt (Co), nickel (Ni), or platinum (Pt) using a physical vapor deposition (PVD) technique or a chemical vapor deposition (CVD) technique and a subsequent high temperature step, although the scope of the invention is not limited in this respect.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A method for fabricating a multi-gate transistor comprising:
depositing a dielectric layer for a spacer on a top surface and a side surface of a semiconductor body;
eroding the dielectric layer to reduce the thickness of the dielectric layer and to expose a top surface of the semiconductor body;
forming a sacrificial layer on the top surface of the semiconductor body;
eroding the dielectric layer to expose the side surface of the semiconductor body; and
eroding the sacrificial layer from the top surface of the semiconductor body.

2. The method of claim 1, wherein forming an epitaxial layer on the top surface and the side surface of the semiconductor body.

3. The method of claim 2, wherein forming a silicide layer on the epitaxial layer.

4. The method of claim 1, wherein the dielectric layer comprises at least one of silicon nitride, titanium nitride, or silicon oxynitride.

5. The method of claim 1, wherein the sacrificial layer comprises an oxide layer.

6. The method of claim 1, wherein eroding the dielectric layer using at least one of a dry-etch process, a wet-etch process, or an ion milling process.

7. The method of claim 1, wherein eroding the sacrificial layer using a wet-etch process.

8. A method of fabricating a multi-gate transistor, comprising:
depositing a dielectric layer on a gate electrode and a side of the semiconductor body;
exposing a top surface of the semiconductor body by etching the dielectric layer;
forming a protective layer on the top surface of the semiconductor body;
exposing the side of the semiconductor body by etching the dielectric layer; and
etching the protective layer from the top surface of the semiconductor body.

9. The method of claim 8, wherein forming an epitaxial layer on the top surface and the side surface of the semiconductor body.

10. The method of claim 9, wherein forming a silicide layer on the epitaxial layer.

11. The method of claim 8, wherein the dielectric layer comprises at least one of silicon nitride, titanium nitride, or silicon oxynitride.

12. The method of claim 8, wherein the protective layer comprises an oxide layer.

13. The method of claim 8, wherein eroding the dielectric layer using at least one of a dry-etch process, a wet-etch process, or an ion milling process.

14. The method of claim 8, wherein eroding the sacrificial layer using a wet-etch process.

15. A multi-gate semiconductor apparatus comprising:
a gate electrode formed on a top surface of a semiconductor body;
a dielectric spacer formed on a side surface of the gate electrode; and
an epitaxial layer formed on the top surface and a side surface of the semiconductor body.

16. The multi-gate semiconductor apparatus of claim 15, wherein a silicide layer is formed on the epitaxial layer.

17. The multi-gate semiconductor apparatus of claim 15, wherein the dielectric spacer comprises at least one of silicon nitride, titanium nitride, or silicon oxynitride.

18. The multi-gate semiconductor apparatus of claim 15, wherein the gate electrode comprises an oxide or a high-K dielectric layer.

19. The multi-gate semiconductor apparatus of claim 18, wherein the high-K dielectric layer comprises at least one of lanthanum oxide, tantalum oxide, titanium oxide, hafnium oxide, zirconium oxide, lead-zirconate-titanate, barium-strontium-titanate, or aluminum oxide.

20. The multi-gate semiconductor apparatus of claim 15, wherein the semiconductor body comprises a silicon substrate or a silicon-on-insulator layer.
